(19) United States
(12) Patent Application Publication
(10) Pub. No.: US 2015/0255162 A1
(43) Pub. Date: Sep. 10, 2015

(54) SEMICONDUCTOR MEMORY DEVICE AND METHOD FOR DETECTING LEAK CURRENT

(71) Applicant: Kabushiki Kaisha Toshiba, Minato-ku (JP)

(72) Inventors: Yuzuru SHIBAZAKI, Fujisawa (JP); Dai NAKAMURA, Fujisawa (JP); Yoshihiko KAMATA, Yokohama (JP)

(73) Assignee: Kabushiki Kaisha Toshiba, Minato-ku (JP)

(21) Appl. No.: 14/482,641

(22) Filed: Sep. 10, 2014

Related U.S. Application Data
(60) Provisional application No. 61/950,530, filed on Mar. 10, 2014.

(51) Int. Cl. G11C 16/26; G11C 5/06

(52) U.S. Cl. CPC G11C 16/26; G11C 5/06

(57) ABSTRACT

According to one embodiment, a semiconductor memory device includes a leak current detection circuit that includes: a detection input end connected to a word line; a first detection end; a coupling circuit connected between the detection input end and the first detection end; a first switching circuit that supplies a voltage to be a reference to the first detection end according to a control signal; and an output circuit that outputs a detection signal corresponding to a change in a voltage of the first detection end caused by the detection input end and the first detection end being coupled by the coupling circuit.

### CROSS-REFERENCE TO RELATED APPLICATIONS

This application is based upon and claims the benefit of priority from U.S. Provisional Application No. 61/950,530, filed on Mar. 10, 2014; the entire contents of which are incorporated herein by reference.

### FIELD

Embodiments described herein relate generally to a semiconductor memory device provided with a leak current detection circuit and a method for detecting a leak current.

### BACKGROUND

In a semiconductor memory device such as a NAND type flash memory, leak current from word lines is becoming a major issue accompanying refinement of manufacturing processes and an increase in a memory capacity. Due to this, a method is being proposed that provides a detection circuit for the leak current from the word lines in a memory chip, compares the leak current detected by the detection circuit with a predetermined threshold, and determines a failure (“FAIL”) when the leak current exceeds the threshold.

In order to increase the memory capacity by making effective use of a chip area of a semiconductor memory device, it is desirable to use a simple circuit with less number of constituent elements for the leak current detection circuit. Further, a configuration with excellent versatility is desirable for the leak current detection circuit.

### BRIEF DESCRIPTION OF THE DRAWINGS

FIG. 1 is a diagram illustrating a semiconductor memory device provided with a leak current detection circuit of a first embodiment.

FIG. 2 is a diagram illustrating one embodiment of a CG driver.

FIG. 3 is a timing chart schematically illustrating a method for detecting a leak current.

FIG. 4 is a diagram illustrating a flow of the method for detecting a leak current.

FIG. 5 is a diagram illustrating a leak current detection circuit of a second embodiment.

FIG. 6 is a timing chart schematically illustrating a method for detecting a leak current of the second embodiment.

FIG. 7 is a diagram illustrating a leak current detection circuit of a third embodiment.

FIG. 8 is a timing chart schematically illustrating a method for detecting a leak current of the third embodiment.

FIG. 9 is a diagram illustrating a leak current detection circuit of a fourth embodiment.

### DETAILED DESCRIPTION

In general, according to one embodiment, a semiconductor memory device includes a leak current detection circuit that includes: a detection input end connected to a word line; a first detection end; a coupling circuit connected between the detection input end and the first detection end, and that electrically couples the detection input end and the first detection end according to a first control signal; a first switching circuit of which output end is connected to the first detection end, and that supplies a voltage to be a reference to the first detection end according to a second control signal; and an output circuit that outputs a detection signal corresponding to a change in a voltage of the first detection end caused by the detection input end and the first detection end being coupled by the coupling circuit responding to the first control signal.

Exemplary embodiments of a semiconductor memory device provided with a leak current detection circuit and a method for detecting a leak current will be explained below in detail with reference to the accompanying drawings. Notably, the invention disclosed herein is not limited to the following embodiments.

### First Embodiment

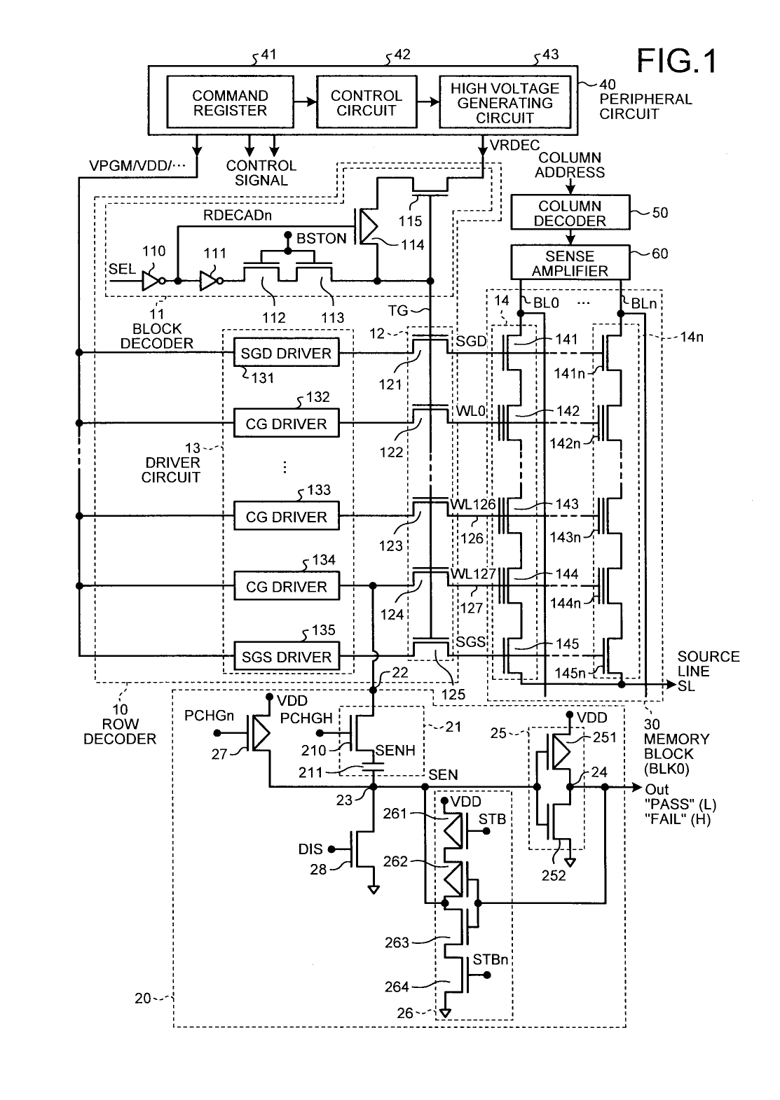

FIG. 1 is a diagram illustrating a semiconductor memory device provided with a leak current detection circuit of a first embodiment. The semiconductor memory device of the embodiment includes a row decoder 10. The row decoder 10 includes a block decoder 11. The block decoder 11 includes an inverter 110 that receives a block selecting signal SEL. The block selecting signal SEL is obtained as a result of calculation by a logic circuit, for example, an AND circuit (not illustrated), that responds to a block address given from outside. The block selecting signal SEL is at an “H” level in a case where it corresponds to a memory block that the block address designates. The block decoder 11 includes an inverter 111 to which an output of the inverter 110 is supplied.

An output of the inverter 111 is supplied to an NMOS transistor 112 and an NMOS transistor 113 of which source-drain passages are serially connected. A signal BSTON is applied to gate electrodes of the NMOS transistor 112 and the NMOS transistor 113. The signal BSTON is a signal that is input upon acquisition of address information by the block decoder 11.

The block decoder 11 includes a PMOS transistor 114 in which the output of the inverter 110 is supplied to a gate electrode. The block decoder 11 includes an NMOS transistor 115 in which a voltage VRDEC is supplied to a drain electrode. The voltage VRDEC is a voltage that is set to a predetermined voltage in accordance with an operation of the semiconductor memory device, that is, in accordance with programming, reading, or erasing and the like of data, and is supplied from a peripheral circuit 40 in accordance with the operation thereof. A source electrode of the NMOS transistor 115 is connected to a source electrode of the PMOS transistor 114, and a drain electrode of the PMOS transistor 114 and a gate electrode of the NMOS transistor 115 are connected. In a state where a block is selected, that is, when the block selecting signal SEL is at the H level, a signal RDECADn supplied to a gate electrode of the PMOS transistor 114 comes to be at a L level, so the PMOS transistor 114 turns on, and the voltage VRDEC supplied to the NMOS transistor 115 is supplied to a gate input TG of a transfer gate 12.

The transfer gate 12 includes a plurality of transfer transistors (121 to 125) having gate electrodes commonly connected. A predetermined voltage is applied from a driver circuit 13 to drain electrodes of the respective transfer transistors (121 to 125). The driver circuit 13 supplies various voltages supplied from the peripheral circuit 40 to the transfer transistors (121 to 125) in accordance with control signals from the peripheral circuit 40.

The driver circuit 13 includes an SGD driver 131, CG drivers (132 to 134), and an SGS driver 135. A selected voltage is supplied from each of the drivers to a corresponding one of the transfer transistors (121 to 125) of the transfer gate 12.

The peripheral circuit 40 is including a command register 41, a control circuit 42, and a high voltage generation circuit 43, and the like. Series of instructions for controlling the semiconductor memory circuit are stored in the command register 41, and it includes an instruction for controlling an operation of the leak current detection circuit described hereinbelow. The control circuit 42 responds to an instruction from the command register 41. The high voltage generation circuit 43 converts a power source voltage VDD to generate a program voltage VPGM to be supplied to a memory transistor that is a program target, an unselected program voltage VPASS to be supplied to other memory transistors and the like under the control of the control circuit 42. The control circuit 42 supplies control signals to the driver circuit 13 and the block decoder 11 configuring the row decoder 10, and a leak current detection circuit 20 to be described later.

The other ends of the respective transfer transistors (121 to 125) of the transfer gate 12 are connected to a memory block 30. The memory block 30 includes a plurality of memory cell units (14, 14n). The memory cell unit 14 includes a selected transistor 141 having a gate electrode connected to a selected gate line SGD connected to a source electrode of the transfer transistor 121, a selected transistor 145 having a gate electrode connected to a selected gate line SGS connected to a source electrode of the transfer transistor 125, and for example 128 pieces of memory cell transistors (142 to 144) having source-drain passages connected serially between the selected transistors 141 and 145.

The memory cell transistors (142 to 144) have a stacked gate structure including a charge accumulating layer (for example floating gate) formed on a semiconductor substrate via a tunnel insulating film, and a control gate formed on the charge accumulating layer via a block insulating film (for example inter gate insulating film). A control electrode of the memory cell transistor 142 is connected to a word line WL0 to which a source electrode of the transfer transistor 122 is connected. The memory cell unit 14 is connected to a bit line BL0.

A source electrode of the selected transistor 145 is connected to a source line SL. Similarly, the memory cell unit 14n includes a selected transistor 141n having a gate electrode connected to the transfer transistor 121, a selected transistor 145n having a gate electrode connected to the transfer transistor 125, and a plurality of memory cell transistors (142n to 144n) having source-drain passages connected serially between the selected transistors 141n and 145n. The memory cell unit 14n is connected to a bit line BLn. A source electrode of the selected transistor 145n is connected to the source line SL. Since the semiconductor memory device of the embodiment configures a NAND type flash memory, the memory cell units (14, 14n) configure memory cell units of the NAND type memory cell. Notably, a plurality of memory blocks which is connected to bit lines (BL0, BLn), is driven by a row decoder (not illustrated) that is separately provided, and has similar configuration is also provided, but omitted. Further, a number of the word lines is not limited to 128.

Each bit line (BL0, BLn) of the memory block 30 is connected to a sense amplifier 60. The sense amplifier 60 is connected to a column decoder 50. The column decoder 50 selects a specific bit line BL, sense amplifier, and the like based on a column address signal that is supplied from outside.

The semiconductor memory device of the embodiment includes the leak current detection circuit 20. The leak current detection circuit 20 includes a detection input end 22. The detection input end 22 is for example connected to a drain electrode of the transfer transistor 124 connected to a word line 127. That is, the detection input end 22 is connected to the word line 127 via the transfer transistor 124. This is for detecting presence or absence of a leak current of the word line 127.

The leak current detection circuit 20 includes a coupling circuit 21 connected between the detection input end 22 and a detection end 23. The coupling circuit 21 includes a NMOS transistor 210 and a capacitor 211. A serial circuit of a source-drain passage of the NMOS transistor 210 and the capacitor 211 is connected between the detection input end 22 and the detection end 23. The detection input end 22 and the detection end 23 are electrically coupled by the NMOS transistor 210 turning on by a control signal PCHGH applied to a gate electrode of the NMOS transistor 210.

The leak current detection circuit 20 includes a PMOS transistor 27 that configures a first switching circuit. A power source voltage VDD is applied to a source electrode of the PMOS transistor 27, and a drain electrode is connected to the detection end 23. The power source voltage VDD is supplied to the detection end 23 when the PMOS transistor 27 turns on by a control signal PCHGn applied to the gate electrode. That is, the detection end 23 is charged to the power source voltage VDD.

The leak current detection circuit 20 includes an output circuit 25. The output circuit 25 includes a PMOS transistor 251 and a NMOS transistor 252 that configures a CMOS inverter. The power source voltage VDD is supplied to a source electrode of the PMOS transistor 251. A drain electrode of the PMOS transistor 251 is connected to a drain electrode of the NMOS transistor 252. A source electrode of the NMOS transistor 252 is grounded. A common connection of the drain electrodes of the PMOS transistor 251 and the NMOS transistor 252 configure an output end 24. The output circuit 25 outputs an output signal Out according to a voltage SEN of the detection end 23.

The leak current detection circuit 20 includes a clocked CMOS inverter 26. The clocked CMOS inverter 26 includes a PMOS transistor 261 in which the power source voltage VDD is applied to the source electrode. A control signal STB is applied to a gate electrode of the PMOS transistor 261. A drain electrode of the PMOS transistor 261 is connected to a source electrode of a PMOS transistor 262. A drain electrode of the PMOS transistor 262 is connected to a drain electrode of an NMOS transistor 263. A source electrode of the NMOS transistor 263 is connected to a drain electrode of an NMOS transistor 264. A source electrode of the NMOS transistor 264 is grounded. A control signal STBn is applied to a gate electrode of the NMOS transistor 264. The control signal STBn is an inverted signal of the control signal STB.

The gate electrodes of the PMOS transistor 262 and the NMOS transistor 263 are commonly connected, and are connected to the output end 24. A common connection end of the drain electrodes of the PMOS transistor 262 and the NMOS transistor 263 is connected to the detection end 23. The clocked CMOS inverter 26 intakes the output signal Out of the output end 24 by synchronizing with the control signals (STB, STBn), and supplies an inverted output thereof to the detection end 23. That is, the output circuit 25 and the clocked CMOS inverter 26 configure a latch circuit that operates in synchrony with the control signals (STB, STBn).

The leak current detection circuit 20 includes an NMOS transistor 28. A drain electrode of the NMOS transistor 28 is connected to the detection end 23, and a source electrode of the NMOS transistor 28 is grounded. A control signal DIS is supplied to a gate electrode of the NMOS transistor 28. The control signal DIS is for example a signal of a ground potential VSS. Workings of the NMOS transistor 28 will be described later.

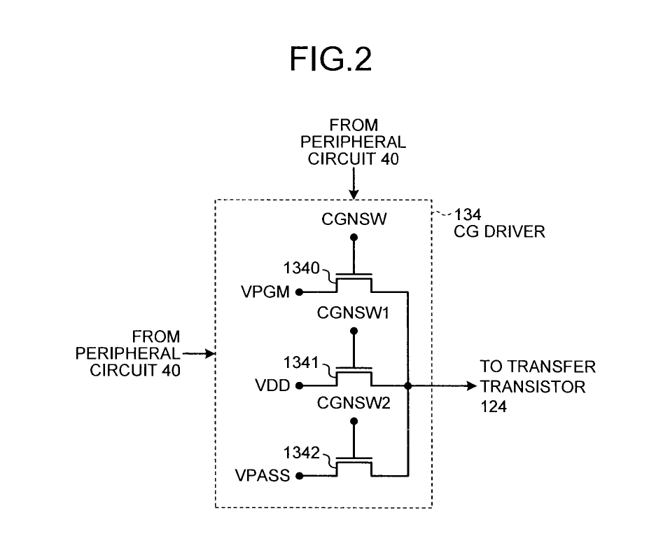

FIG. 2 is a diagram illustrating one embodiment of a CG driver. As a representative example, the CG driver 134 connected to the transfer transistor 124 is illustrated. The CG driver 134 includes NMOS transistors (1340 to 1342), source electrodes of which are commonly connected. For example, a program voltage VPGM for a memory is applied to a drain electrode of the NMOS transistor 1340. Similarly, the power source voltage VDD is supplied to a drain electrode of the NMOS transistor 1341, and an unselected program voltage VPASS is supplied to a drain electrode of the NMOS transistor 1342.

Specific NMOS transistors (1340 to 1342) of the CG driver 134 comes to be in an on state by a control signal supplied from the peripheral circuit 40, and a voltage supplied to the drain electrode of the NMOS transistor in the on state is supplied to the transfer transistor 124. For example, the program voltage VPGM is supplied to the transfer transistor 124 by the NMOS transistor 1340 turning on by a control signal CGNSW.

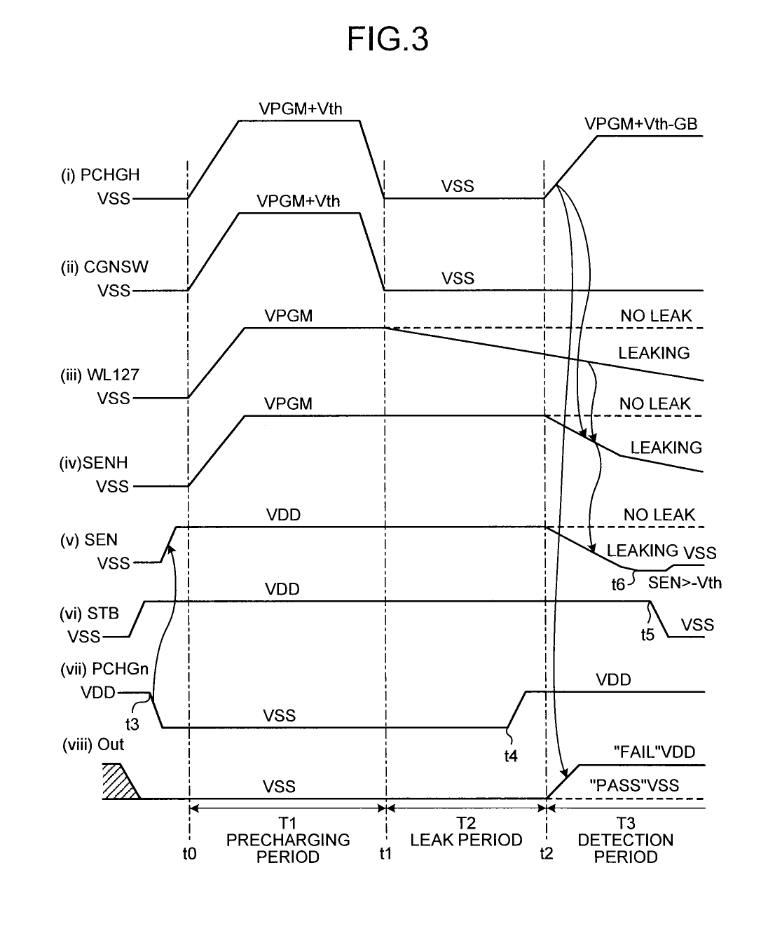

Next, a method of detecting the leak current by the leak current detection circuit 20 will be described by using FIG. 3. The description will be given with a state in which the signal SEL supplied to the block decoder 11 is at the H level, and the memory block 30 is being selected as the premise. FIG. 3 illustrates, from its upper row: (i) a control signal PCHGH supplied to the NMOS transistor 210 of the coupling circuit 21, (ii) a control signal CGNSW supplied to the gate electrode of the NMOS transistor 1340 of the CG driver 134, (iii) a voltage WL127 of the word line 127, (iv) a voltage SENH at a connecting part of the NMOS transistor 210 and the capacitor 211 of the coupling circuit 21, (v) a voltage SEN of the detection end 23, (vi) a control signal STB supplied to the clocked CMOS inverter 26, (vii) a control signal PCHGn applied to the gate electrode of the PMOS transistor 27 configuring the first switching circuit, and (viii) an output signal Out.

Firstly, at timing t3, the control signal PCHGn applied to the gate electrode of the PMOS transistor 27 configuring the first switching circuit comes to be in an L level, and the PMOS transistor 27 turns on. Due to this, the power source voltage VDD is supplied to the detection end 23, and the detection end 23 is charged to the power source voltage VDD.

Next, at timing t0, the control signal PCHGH applied to the gate electrode of the NMOS transistor 210 of the coupling circuit 21 and the control signal CGNSW applied to the gate electrode of the NMOS transistor 1340 of the CG driver 134 are brought to an H level, and the NMOS transistor 210 and the NMOS transistor 1340 are turned on. The levels of the control signal PCHGH and the control signal CGNSW at this occasion are for example set at a voltage that is higher than the program voltage VPGM by a threshold voltage Vth. The voltage SENH at the connecting part of the NMOS transistor 210 and the capacitor 211 of the coupling circuit 21 comes to be the program voltage VPGM by the NMOS transistor 210 having turned on. Further, the voltage WL127 of the word line 127 also comes to be the program voltage VPGM.

At timing t1 when a predetermined time has elapsed, the control signal PCHGH and the control signal CGNSW are brought to an L level, and the NMOS transistor 210 of the coupling circuit 21 and the NMOS transistor 1340 of the CG driver 134 are turned off. The voltage levels of the control signal PCHGH and the control signal CGNSW at this occasion are for example at the ground potential VSS. The detection input end 22 and the detection end 23 can be electrically cut off by turning off the NMOS transistor 210 of the coupling circuit 21. Further, supply of the program voltage VPGM through the CG driver 134 is stopped by turning off the NMOS transistor 1340 of the CG driver 134. In a case where a leak current is present in the word line 127, the voltage WL127 of the word line 127 begins to decrease after the timing t1. In a case where no leak current is present in the word line 127, the word line 127 maintains the program voltage VPGM.

Next, at timing t4, the control signal PCHGn supplied to the gate electrode of the PMOS transistor 27 configuring the first switching circuit is brought to be at the H level. For example, it is set to the voltage of the power source voltage VDD. Due to this, the PMOS transistor 27 turns off. Charging operation of the detection end 23 through the PMOS transistor 27 stops by the PMOS transistor 27 having turned off. A period T1 from timing t0 to timing t1 is termed a precharging period.

Next, at timing t2, the control signal PCHGH supplied to the gate electrode of the NMOS transistor 210 of the coupling circuit 21 is brought to the H level. The voltage of the control signal PCHGH at this occasion is for example a voltage that is lower by a voltage GB than a voltage in which the threshold voltage Vth is added to the program voltage VPGM. This voltage GB is a voltage that takes into consideration a voltage drop that is not caused by the leak current from the word line 127, for example, a voltage drop caused by a transistor and the like existing on a path to the word line 127. Reliability of the detection of the leak current of the word line 127 can be improved by controlling conduction of the NMOS transistor 210 of the coupling circuit 21 by the voltage that is lowered by the voltage GB expected to be caused by the cause other than the leak current of the word line 127. A period T2 from timing t1 to timing t2 is termed a leak period in which a state of the leak current of the word line 127 is observed.

At timing t2, the detection input end 22 and the detection end 23 are electrically coupled by the NMOS transistor 210 of the coupling circuit 21 having turned on. Due to this, a detection period T3 starts. Firstly, the voltage SENH of the connecting part of the NMOS transistor 210 and the capacitor 211 is connected to the word line 127 by the NMOS transistor 210 having turned on. Due to this, in the case where there is a leak current in the word line 127 and the voltage WL127 is decreased, a change thereof is reflected in the voltage SENH of the connecting part. Moreover, the change in the voltage of the voltage SENH of the connecting part is reflected in the voltage SEN of the detection end 23. In the case where there is no leak current and there is no change in the voltage WL127 in the word line 127, the voltage SENH of the connecting part and the voltage SEN of the detection end 23 do not change.

When the voltage SEN of the detection end 23 decreases over a circuit threshold of the CMOS inverter configuring the output circuit 25, the output circuit 25 outputs the H level signal Out. That is, in the case where the leak current is present in the word line 127, the output circuit 25 outputs the H level signal as an output indicating “FAIL”. To the contrary, in the case where there is no leak current, the output circuit 25 outputs an L level signal as an output indicating “PASS”. The H level is the power source voltage VDD, and the L level is the ground potential VSS. The output signal Out of the output circuit 25 indicating the detection result is output for example to outside the semiconductor memory device.

At timing t5, the control signal STB supplied to the clocked CMOS inverter 26 is set to the L level. At this timing t5, the output signal Out is taken into the clocked CMOS inverter 26. That is, the signal level of the output signal Out taken in at timing t5 is retained by the latch circuit including the output circuit 25 and the clocked CMOS inverter 26. By suitably selecting the timing t5, the output signal Out at a state where the output circuit 25 is stabilized can be retained.

Since the voltage SEN of the detection end 23 fluctuates by reflecting the voltage WL127 of the word line 127, there is a possibility that the voltage SEN of the detection end 23 swings drastically to the ground potential VSS or lower in a case where the leak current of the word line 127 is large. In the leak current detection circuit 20 of the embodiment, the NMOS transistor 28 turns on when a potential of the detection end 23 decreases lower than the ground potential VSS by the threshold voltage Vth or more. Due to this, the voltage SEN of the detection end 23 is ensured to be in a range of SEN>−Vth. That is, the NMOS transistor 28 serves a function of a clamp element. Thus, since a situation in which an excessive voltage is applied to the output circuit 25 is avoided, circuit elements can be protected from being broken. For example, the voltage SEN of the detection end 23 illustrated in (v) of FIG. 3 decreases below the ground potential VSS at timing t6, however the NMOS transistor 28 turns on when the voltage SEN decreases lower than the ground potential VSS by the threshold voltage Vth or more, and the voltage SEN comes to be at the ground potential VSS. Notably, a diode may be used as the clamp element instead of the NMOS transistor 28. In this case, an anode electrode of a diode (not illustrated) is grounded, and a cathode electrode is connected to the detection end 23.

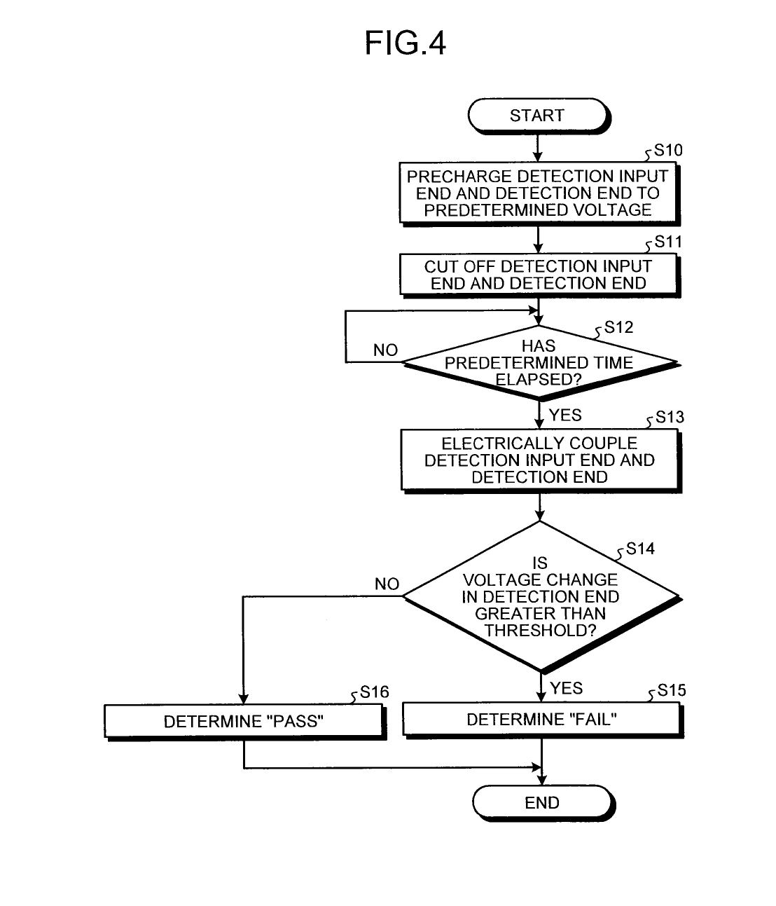

FIG. 4 is a flow chart of a detection operation of the leak current detection circuit 20 of the embodiment. As illustrated in the drawing, firstly, the detection input end 22 and the detection end 23 are precharged to a predetermined voltage (step S10). As described in FIG. 3, for example, the detection input end 22 is precharged to the program voltage VPGM by the program voltage VPGM being applied to the word line 127 connected to the detection input end 22. The detection end 23 is precharged for example to the power source voltage VDD.

Next, the detection input end 22 and the detection end 23 are cut off (step S11). The detection input end 22 and the detection end 23 are electrically cut off by turning off the NMOS transistor 210 configuring the coupling circuit 21. The leak period T2 illustrated in FIG. 3 starts with the detection input end 22 and the detection end 23 having been electrically cut off.

A determination is made as to whether a predetermined time has elapsed in the leak period T2 (step S12). By setting this leak period T2 suitably, the period to observe the leak current of the word line is determined. That is, if the leak period T2 is set long, a possibility that the determination that the leak current is present is made, that is, the output signal Out becomes “FAIL” (H level) becomes high despite the leak current being small.

The detection input end 22 and the detection end 23 are electrically coupled after the predetermined time T2 has elapsed (step S13). The detection input end 22 and the detection end 23 is electrically coupled by turning on the NMOS transistor 210 configuring the coupling circuit 21.

The change in the voltage of the detection end 23 caused by the detection input end 22 and the detection end 23 being electrically coupled is determined whether it is larger than a predetermined threshold or not (step S14). In a case where the voltage SEN of the detection end 23 decreases beyond the circuit threshold of the CMOS inverter configuring the output circuit 25, the output circuit 25 outputs the H level signal indicating that the leak current is present (“FAIL”) (step S15). To the contrary, in a case where a fluctuation of the voltage SEN of the detection end 23 is smaller than the circuit threshold, the output circuit 25 outputs the L level signal indicating that the leak current does not exist (“PASS”) (step S16).

According to the embodiment, the presence/absence of the leak current of the word line 127 can be detected by comparing the change in the potential of the detection end 23 caused by the electrically coupling the detection input end 22 and the detection end 23 by the coupling circuit 21 at the predetermined timing with the circuit threshold of the output circuit 25. Further, the coupling circuit 21 includes the capacitor 211. Due to this, the voltage of the detection input end 22 and the voltage of the detection end 23 can be set to different voltages at a stage of initial settings. In the case of the foregoing embodiment, the voltage of the detection input end 22 can be set to the program voltage VPGM, and the voltage SEN of the detection end 23 can be set to the power source voltage VDD. Due to this, versatility of the voltage settings that are target of detection can be improved.

Further, in the present embodiment, although a configuration in which the detection input end 22 is connected only to the drain electrode of the transfer transistor 124 connected to the word line 127 is described, a number of the coupling circuit 21 can be increased in accordance with a number of the detection target, and presence/absence of the leak current in all of the word lines can be detected by configuring to connect a corresponding detection input end 22 to the drain electrode of each of the transfer transistors (122 to 124) connected to word lines, for example. That is, simply increasing the coupling circuit 21 can provide configurations that can detect the leak current of all of the word lines.

### Second Embodiment

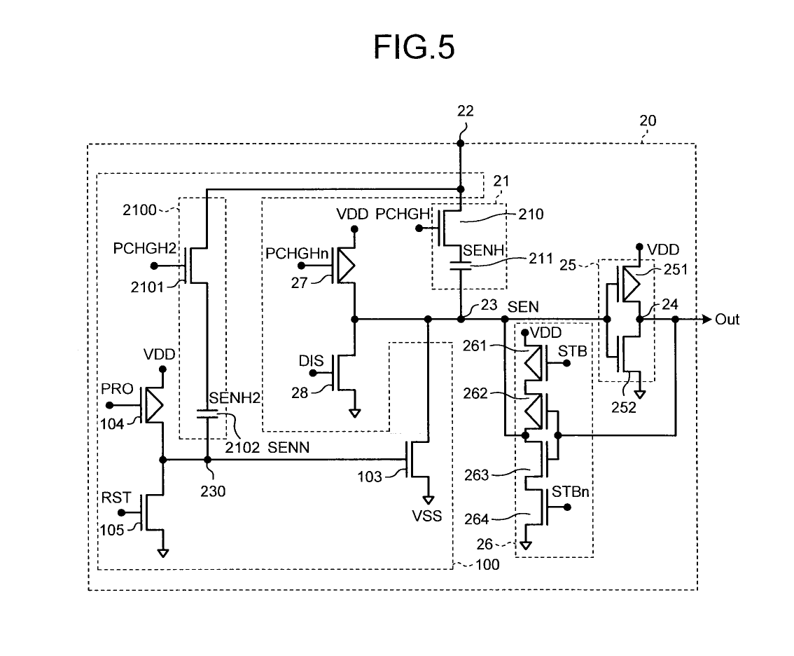

FIG. 5 is a diagram illustrating a leak current detection circuit of a second embodiment. Same reference signs will be given to configurations corresponding to the aforestated embodiment, and overlapping description will be given only if needed. A leak current detection circuit 20 of the embodiment includes a second circuit unit 100. The second circuit unit 100 includes a second coupling circuit 2100. The second coupling circuit 2100 includes an NMOS transistor 2101, a drain electrode of which is connected to a detection input end 22. A source electrode of the NMOS transistor 2101 is connected to one end of a capacitor 2102. The other end of the capacitor 2102 is connected to a second detection end 230. A control signal PCHGH2 is applied to a gate electrode of the NMOS transistor 2101.

The second circuit unit 100 includes a PMOS transistor 104 in which a power source voltage VDD is applied to the source electrode, and drain electrode of which is connected to a second detection end 230. A control signal PRO is applied to a gate electrode of the PMOS transistor 104. As the control signal PRO, for example, the power source voltage VDD is applied.

The second circuit unit 100 includes a NMOS transistor 105, a drain electrode of which is connected to the second detection end 230, and source electrode is grounded. A control signal RST is applied to a gate electrode of the NMOS transistor 105.

The second circuit unit 100 includes a NMOS transistor 103, a drain electrode of which is connected to a first detection end 23, and a source electrode is grounded. A gate electrode of the NMOS transistor 103 is connected to the second detection end 230.

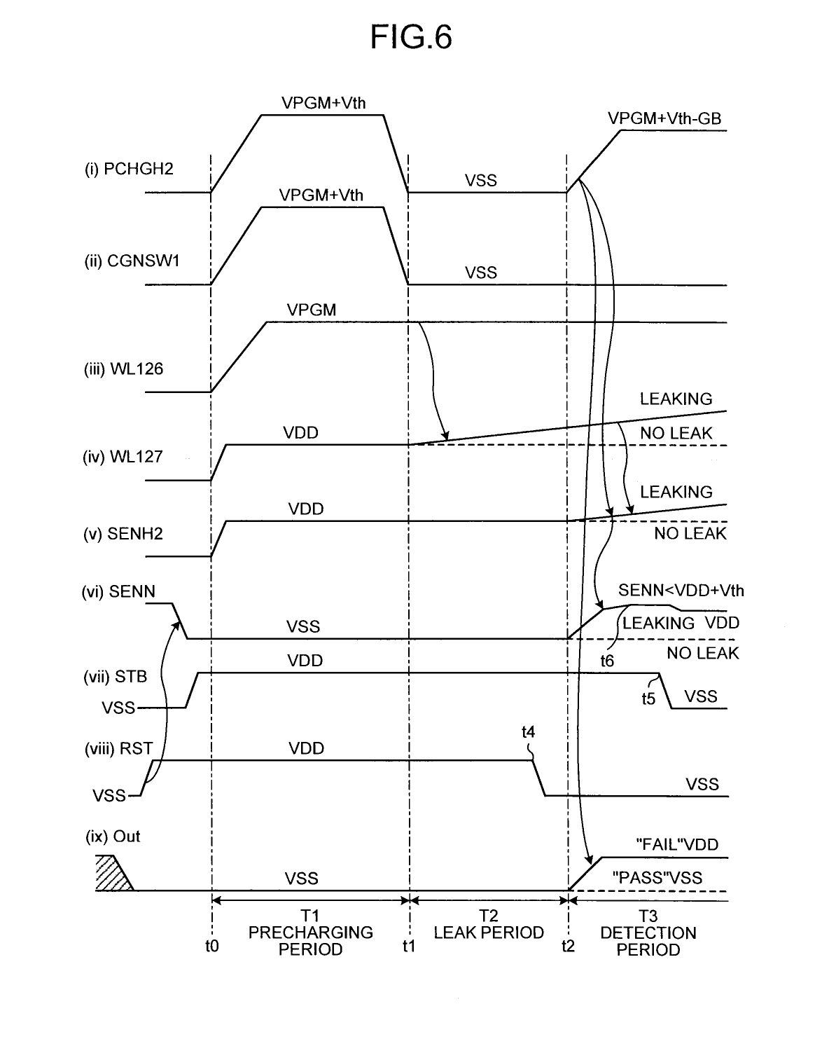

Similar to the case of the first embodiment, the detection input end 22 is for example connected to a drain electrode of a transfer transistor 124 connected to a word line 127 illustrated in FIG. 1. This is for detecting presence or absence of a leak current in the word line 127. A step that determines the presence or absence of the leak current by applying program voltage VPGM to the word line 127, and comparing a potential change in the detection end 23 generated after a predetermined time with a predetermined threshold is a described earlier. By being provided with the second circuit unit 100, versatility of leak current detection is increased. Hereinbelow, a circuit operation thereof will be described by using FIG. 6. Notably, in order to electrically cut off a coupling circuit 21 from the detection end 23, a control signal PCHGH applied to a gate electrode of an NMOS transistor 210 is at an L level.

FIG. 6 illustrates, from its upper row: (i) a control signal PCHGH2 supplied to the NMOS transistor 2101 of the second coupling circuit 2100, (ii) a control signal CGNSW1 supplied to a gate electrode of a NMOS transistor 1341 of a CG driver 134, (iii) a voltage WL126 of a word line 126, (iv) a voltage WL127 of a word line 127, (v) a voltage SENH2 at a connecting part of the NMOS transistor 2101 and the capacitor 2102 of the second coupling circuit 2100, (vi) a voltage SENN of the second detection end 230, (vii) a control signal STB supplied to a clocked CMOS inverter 26, (viii) a control signal RST applied to a gate electrode of an NMOS transistor 105, and (ix) an output signal Out.

Firstly, the control signal RST applied to the gate electrode of the NMOS transistor 105 comes to be at an H level, and the NMOS transistor 105 turns on. Due to this, a ground potential VSS is supplied to the second detection end 230, and the second detection end 230 comes to be at the ground potential VSS.

Next, at timing t0, the control signal PCHGH2 applied to the gate electrode of the NMOS transistor 2101 of the second coupling circuit 2100 and the control signal CGNSW1 applied to the gate electrode of the NMOS transistor 1341 of the CG driver 134 are brought to an H level, and the NMOS transistor 2101 and the NMOS transistor 1341 are turned on. The levels of the control signal PCHGH2 and the control signal CGNSW1 at this occasion are for example set at a voltage that is higher than the program voltage VPGM by a threshold voltage Vth. The voltage SENH2 at the connecting part of the NMOS transistor 2101 and the capacitor 2102 of the second coupling circuit 2100 comes to be the power source voltage VDD by the NMOS transistor 2101 having turned on. Further, the voltage WL127 of the word line 127 also comes to be the power source voltage VDD. Notably, it is assumed that the program voltage VPGM is applied to the adjacent word line 126. The program voltage VPGM can be supplied to the word line 126 by the CG driver 133 connected to the word line 126. A period T1 from timing t0 to timing t1 is termed a precharging period.

At timing t1 when a predetermined time has elapsed, the control signal PCHGH2 and the control signal CGNSW1 are brought to an L level, and the NMOS transistor 2101 of the second coupling circuit 2100 and the NMOS transistor 1341 of the CG driver 134 are turned off. The voltage levels of the control signal PCHGH2 and the control signal CGNSW1 at this occasion are for example at the ground potential VSS. The detection input end 22 and the second detection end 230 can be electrically cut off by turning off the NMOS transistor 2101 of the second coupling circuit 2100. Further, supply of the power source voltage VDD through the CG driver 134 is stopped by turning off the NMOS transistor 1341 of the CG driver 134. In a case where a leak current is present in the word line 127 from the adjacent word line 126, the voltage WL127 of the word line 127 begins to increase after the timing t1. In a case where no leak current is present from the word line 126, the word line 127 maintains the power source voltage VDD.

Next, at timing t4, the control signal RST supplied to the gate electrode of the NMOS transistor 105 is brought to the L level. For example, it is set to the ground potential VSS. Due to this, the NMOS transistor 105 turns off. The supply of the ground potential to the second detection end 230 through the NMOS transistor 105 is stopped by the NMOS transistor 105 having turned off.

Next, at timing t2, the control signal PCHGH2 supplied to the gate electrode of the NMOS transistor 2101 of the second coupling circuit 2100 is brought to the H level, and the NMOS transistor 2101 is turned on. A period T2 from timing t1 to timing t2 is termed a leak period in which a state of the leak current of the word line 127 is observed.

At timing t2, the detection input end 22 and the second detection end 230 are electrically coupled by the NMOS transistor 2101 of the second coupling circuit 2100 having turned on. Due to this, a detection period T3 starts. Firstly, the voltage SENH2 of the connecting part of the NMOS transistor 2101 and the capacitor 2102 is connected to the word line 127 by the NMOS transistor 2101 having turned on. Due to this, in the case where there is a leak current from the adjacent word line 126, the potential of the word line 127 is increased, and a change thereof is reflected in the voltage SENH2 of the connecting part. Moreover, the change in the voltage of the voltage SENH2 of the connecting part is reflected in the voltage SENN of the second detection end 230. In the case where there is no leak current from the adjacent word line 126 and there is no change in the voltage WL127 in the word line 127, the voltage SENH2 of the connecting part and the voltage SENN of the second detection end 230 do not change.

The NMOS transistor 103 turns on when the voltage SENN of the second detection end 230 increases beyond the threshold voltage Vth of the NMOS transistor 103, and the voltage SEN of the detection end 23 is brought to the ground potential VSS. Due to this, the output circuit 25 outputs a signal Out at an H level. That is, in the case where the leak current is present in the word line 127 from the adjacent word line 126, the output circuit 25 outputs the H level signal as an output indicating “FAIL”. To the contrary, in the case where there is no leak current from the word line 126, the output circuit 25 outputs an L level signal as an output indicating “PASS”. The H level is the power source voltage VDD, and the L level is the ground potential VSS.

At timing t5, the control signal STB supplied to the clocked CMOS inverter 26 is set to the L level. At this timing t5, the output signal Out is taken into the clocked CMOS inverter 26. That is, the signal level of the output signal Out taken in at timing t5 is retained by the latch circuit including the output circuit 25 and the clocked CMOS inverter 26.

Since the voltage SENN of the second detection end 230 fluctuates by reflecting the voltage WL127 of the adjacent word line 127, there is a possibility that the voltage SENN of the second detection end 230 may swing drastically beyond the power source voltage VDD. In the leak current detection circuit 20 of the embodiment, the PMOS transistor 104 turns on when a potential of the second detection end 230 increases above the power source voltage VDD by the threshold voltage Vth or more. Due to this, the voltage SENN of the second detection end 230 is ensured to be in a range of SENN<VDD+Vth. That is, the PMOS transistor 104 serves a function of a clamp element. Thus, since a situation in which an excessive voltage is applied to the gate electrode of the NMOS transistor 103 is avoided, it can be protected from being broken. The voltage SENN of the second detection end 230 illustrated in (vi) of FIG. 6 increases beyond the power source voltage VDD at timing t6, however the PMOS transistor 104 turns on when the voltage SENN increases beyond the power source voltage VDD by the threshold voltage Vth or more, and the voltage SENN comes to be the power source voltage VDD. Notably, a diode may be used as the clamp element instead of the PMOS transistor 104. In this case, an anode electrode of a diode (not illustrated) is connected to the second detection end 230, and the power source voltage VDD is applied to a cathode electrode.

According to the second embodiment, the versatility of the detection of the word lines that are targets of detection and to which the detection input end 22 is connected can be expanded by providing the second circuit unit 100. That is, in addition to the detection of the presence/absence of the leak current of the word line 127 itself to which the detection input end 22 is connected, the presence/absence of the leak current from the adjacent word line 126 can be detected by operating the second circuit unit 100. In the present embodiment also, the presence/absence of the leak current of all of the word lines can be detected by increasing numbers of the coupling circuit 21 and the second coupling circuit 2100 in accordance with a number of the detection targets. That is, simply increasing the coupling circuit 21 and the second coupling circuit 2100 can provide configurations that can detect the leak current of all of the word lines.

### Third Embodiment

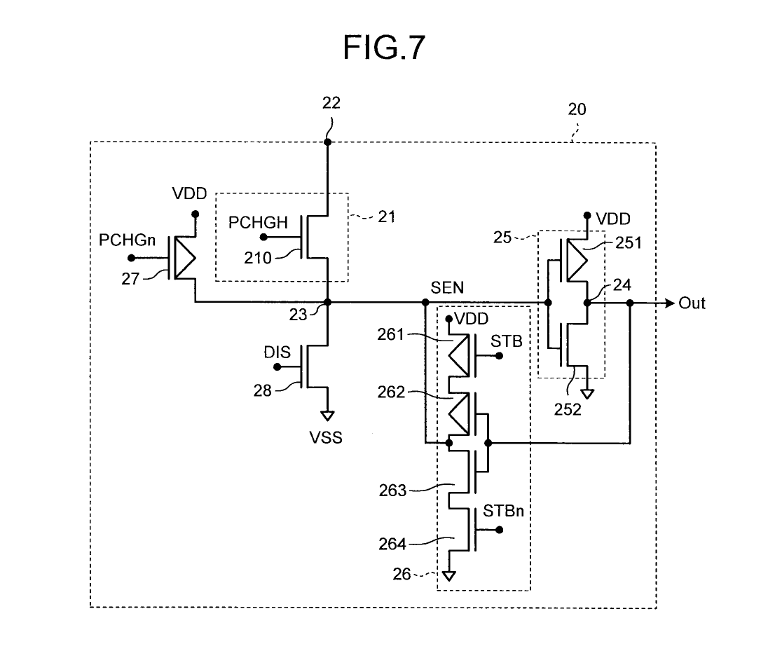

FIG. 7 is a diagram illustrating a leak current detection circuit of a third embodiment. Same reference signs will be given to configurational elements corresponding to the aforestated embodiments, and overlapping description will be given only if needed. In the leak current detection circuit 20 of the present embodiment, a coupling circuit 21 includes an NMOS transistor 210. That is, a capacitor 211 that the aforestated embodiments had is not provided.

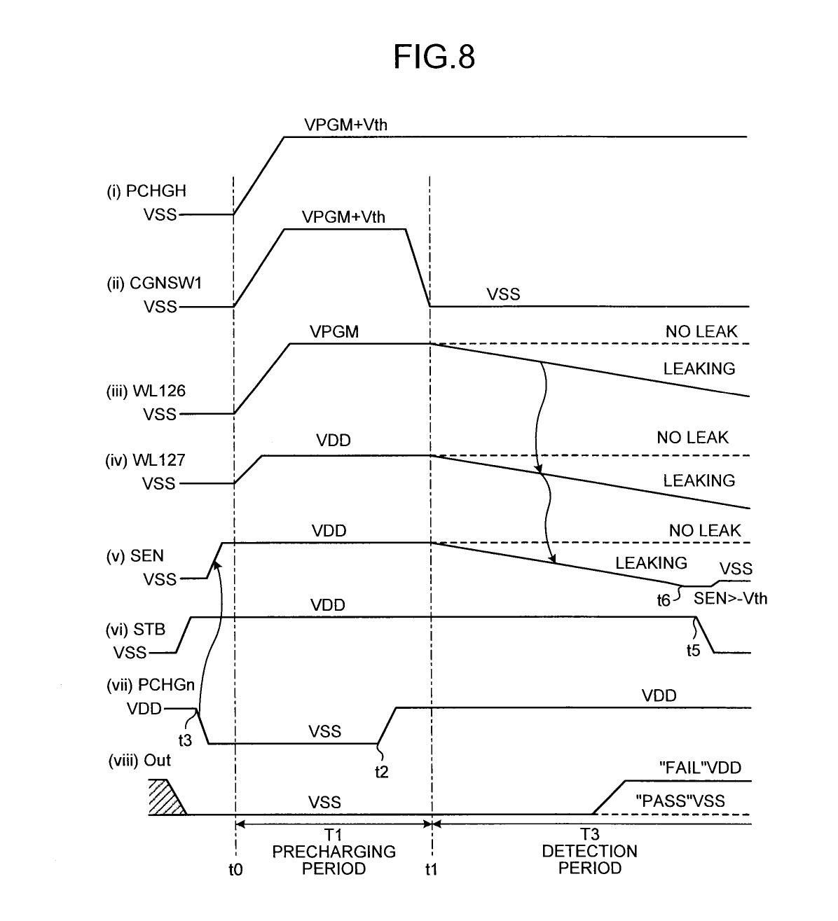

Next, a method of detecting a leak current by the leak current detection circuit 20 of the present embodiment will be described by using FIG. 8. FIG. 8 illustrates, from its upper row: (i) a control signal PCHGH supplied to the NMOS transistor 210 of the coupling circuit 21, (ii) a control signal CGNSW1 supplied to a gate electrode of an NMOS transistor 1341 of a CG driver 134, (iii) a voltage WL126 of an adjacent word line 126, (iv) a voltage WL127 of a word line 127 that is a detection target, (v) a voltage SEN of the detection end 23, (vi) a control signal STB supplied to a clocked CMOS inverter 26, (vii) a control signal PCHGn applied to a gate electrode of a PMOS transistor 27 configuring a first switching circuit, and (viii) an output signal Out.

Firstly, at timing t3, the control signal PCHGn applied to the gate electrode of the PMOS transistor 27 configuring the first switching circuit comes to be in an L level, and the PMOS transistor 27 turns on. Due to this, a power source voltage VDD is supplied to a detection end 23, and the voltage SEN of the detection end 23 is charged to the power source voltage VDD.

Next, at timing t0, the control signal PCHGH applied to the gate electrode of the NMOS transistor 210 of the coupling circuit 21 and the control signal CGNSW1 applied to a gate electrode of an NMOS transistor 1341 of the CG driver 134 are brought to an H level, and the NMOS transistor 210 and the NMOS transistor 1341 are turned on. The levels of the control signal PCHGH and the control signal CGNSW1 at this occasion are for example set at a voltage that is higher than a program voltage VPGM by a threshold voltage Vth. The voltage WL127 of the word line 127 comes to be the power source voltage VDD by the NMOS transistor 1341 of the CG driver 134 having turned on. Notably, the adjacent word line 126 is precharged to the program voltage VPGM. Notably, the voltage VL126 of the word line 126 is charged to the program voltage VPGM by supplying the program voltage VPGM from a CG driver 133 connected to the word line 126. Control of the CG driver 133 is performed by control complying with the control signal CGNSW supplied to the NMOS transistor 1340 of the CG driver 134.

At timing t1 when a predetermined time has elapsed, the control signal CGNSW1 is brought to an L level, and the NMOS transistor 1341 of the CG driver 134 is turned off. The voltage level of the control signal CGNSW1 is for example at a ground potential VSS. Further, supply of the power source voltage VDD to the word line 127 through the CG driver 134 is stopped by turning off the NMOS transistor 1341 of the CG driver 134. Notably, prior to timing t1, at timing t2 a control signal PCHGn applied to a gate electrode of the PMOS transistor 27 configuring a first switching circuit is brought to an H level, and the PMOS transistor 27 is turned off. Due to this, supply of the power source voltage VDD to the detection end 23 by the PMOS transistor 27 is stopped.

In a case where a leak current is present in the adjacent word line 126, the voltage WL126 of the word line 126 begins to decrease after the timing t1. In a case where no leak current is present in the word line 126, the word line 126 maintains the program voltage VPGM. Decrease of the voltage WL126 of the word line 126 is reflected in the voltage WL127 of the word line 127. That is, the voltage WL127 of the word line 127 decreases. Decrease of the voltage WL127 of the word line 127 causes decrease in the voltage SEN of the detection end 23. When the voltage SEN of the detection end 23 decreases over a circuit threshold of the CMOS inverter configuring the output circuit 25, the output circuit 25 outputs the H level signal Out. That is, the output signal Out indicating “FAIL” that notifies the occurrence of the leak current in the adjacent word line 126 is output. In a case where the decrease of the voltage SEN of the detection end 23 does not exceed the threshold of an output circuit 25, the output circuit 25 outputs an L level output signal Out indicating “PASS”.

Since the voltage SEN of the detection end 23 fluctuates by reflecting the voltage WL126 of the word line 126, there is a possibility that the voltage SEN of the detection end 23 swings drastically to the ground potential VSS or lower in a case where the leak current of the word line 126 is large. In the leak current detection circuit 20 of the embodiment, an NMOS transistor 28 turns on when a potential of the detection end 23 decreases lower than the ground potential VSS by the threshold voltage Vth or more. Due to this, the voltage SEN of the detection end 23 is ensured to be in a range of SEN>−Vth. That is, the NMOS transistor 28 serves a function of a clamp element. Thus, since a situation in which an excessive voltage is applied to the output circuit 25 is avoided, circuit elements can be protected from being broken. For example, the voltage SEN of the detection end 23 illustrated in (v) of FIG. 8 decreases below the ground potential VSS at timing t6, however the NMOS transistor 28 turns on when the voltage SEN of the detection end 23 decreases lower than the ground potential VSS by the threshold voltage Vth or more, and the voltage SEN comes to be at the ground potential VSS. Notably, a diode may be used as the clamp element instead of the NMOS transistor 28. In this case, an anode electrode of a diode (not illustrated) is grounded, and a cathode electrode is connected to the detection end 23.

At timing t5, the control signal STB supplied to the clocked CMOS inverter 26 is set to the L level. At this timing t5, the output signal Out is taken into the clocked CMOS inverter 26. That is, the signal level of the output signal Out taken in at timing t5 is retained by the latch circuit including the output circuit 25 and the clocked CMOS inverter 26. By suitably selecting the timing t5, the output signal Out at a state where the output circuit 25 is stabilized can be retained.

According to the embodiment, by setting an initial value of the voltage SEN of the detection end 23 at the power source voltage VDD, the presence/absence of the leak current of the adjacent word line 126 can be detected indirectly. Further, since an initial value of the word line 127 to which the detection input end 22 is connected is for example the power source voltage VDD, the configuration of the leak current detection circuit 20 not provided with the capacitor 211 in the coupling circuit 21 can be made. Moreover, since the PMOS transistor 27 that clamps the voltage SEN of the detection end 23 to a voltage that is equal to or less than the power source voltage VDD+threshold voltage Vth, an excessive voltage is suppressed from being applied to a circuit element configuring the output circuit 25, and the circuit element can be protected from damages. In the present embodiment also, the presence/absence of the leak current of all of the word lines can be detected by increasing a number of the coupling circuit 21 in accordance with a number of the detection targets.

### Fourth Embodiment

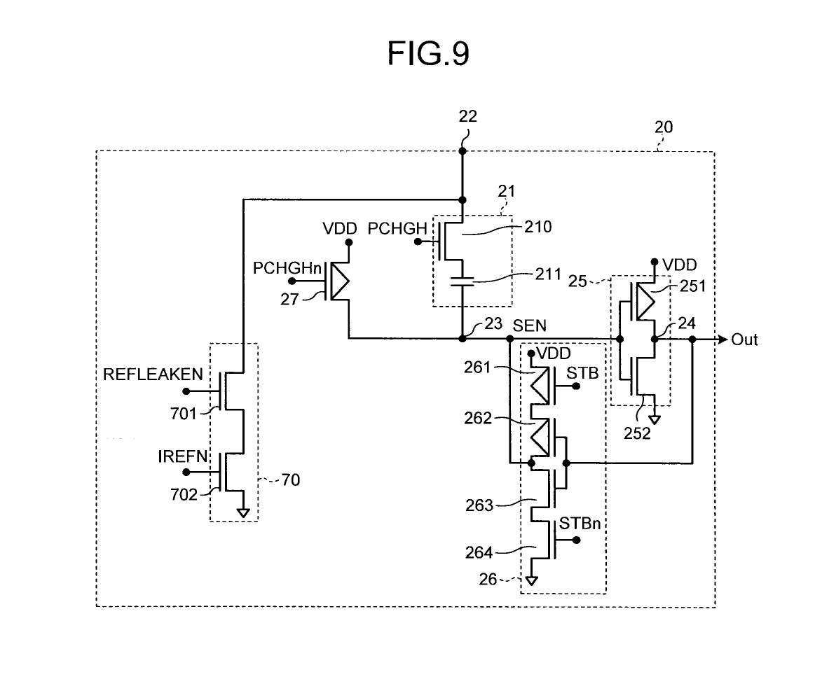

FIG. 9 is a diagram illustrating a leak current detection circuit of a fourth embodiment. Same reference signs will be given to configurational elements corresponding to the aforestated embodiments, and overlapping description will be given only if needed. A leak current detection circuit 20 of the embodiment includes a constant current circuit 70. The constant current circuit 70 includes an NMOS transistor 701, a drain electrode of which is connected to a detection input end 22. The constant current circuit 70 includes a NMOS transistor 702. A drain electrode of the NMOS transistor 702 is connected to a source electrode of an NMOS transistor 701, and a source electrode is grounded. A control signal REFLEAKEN is applied to a gate electrode of the NMOS transistor 701, and a control signal IREFN is applied to a gate electrode of the NMOS transistor 702. Conduction of the constant current circuit 70 is controlled by the control signal REFLEAKEN, and a current value of the constant current circuit 70 is controlled by the control signal IREFN.

For example, detection of a presence or absence of a leak current in a word line is performed in a state where the constant current circuit 70 is turned off. The detection is performed by turning the constant current circuit 70 on in a case where the presence of the leak current is detected. In this case, the detection is performed in a state by which the detection input end 22 is cut off from the word line that is a detection target for example. A magnitude of the leak current in the detection target word line can be identified by performing detection by suitably setting the current value of the constant current circuit 70 in a time that is identical to a leak period T2 in the case of the detection of the presence of the leak current, and calculating a critical current value by which “FAIL” (H level) indicating the presence of the leak current is to be output as the output signal Out. In the present embodiment also, the presence/absence of the leak current of all of the word lines and the magnitude of the leak current can be detected by increasing numbers of the coupling circuit 21 and the constant current circuit 70 in accordance with a number of the detection targets.

Two leak current detection circuits may be provided in a configuration, and one leak current detection circuit may be connected to even-numbered word lines (0th, 2nd, . . . , 126th), and the other leak current detection circuit may be connected to odd-numbered word lines (1st, 3rd, . . . , 127th). For example, a power source voltage VDD may be applied to the even-numbered word lines, and an input detection end connected to these even-numbered word lines, and a first leak current detection circuit having a coupling circuit that couples between the detection input end and the detection end is provided. Similarly, a program voltage VPGM may be applied to the odd-numbered word lines, and an input detection end connected to these odd-numbered word lines, and a second leak current detection circuit having a coupling circuit that couples between the detection input end and the detection end is provided. By performing detection by the above described detection steps using the first and second leak current detection circuits, a presence or absence of a leak current in an even-numbered word line from an adjacent odd-numbered word line, and presence or absence of a leak current of an odd-numbered word line can be detected at once. The leak current detection circuit of the first embodiment described in FIG. 1 may be used as the first leak current detection circuit, and the leak current detection circuit of the third embodiment described in FIG. 7 may be used as the second current detection circuit. Alternatively, as the first and second leak current detection circuits, the leak current detection circuit of the second embodiment described in FIG. 5 may be used, and the first leak current detection circuit may be used in a configuration that uses the second circuit unit 100, and the second leak current detection circuit may be used in a configuration that does not use the second circuit unit 100.

The cases in which the leak current of the word line were described as examples, however, implementation may similarly be made for cases of detecting a leak current of bit lines. Alternatively, it may be adapted to cases of detecting leak currents of both the word lines and the bit lines. A leak current detection circuit may include a second detection input end connected to bit lines, and the second detection input end and a detection end may be coupled by a coupling circuit, whereby the leak currents of the word lines and the bit lines can be detected.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising a leak current detection circuit that includes:
a detection input end connected to a word line;
a first detection end;
a coupling circuit connected between the detection input end and the first detection end, the coupling circuit electrically couples the detection input end and the first detection end according to a first control signal;
a first switching circuit having an output end connected to the first detection end, the first switching circuit supplies a voltage to be a reference to the first detection end according to a second control signal; and
an output circuit that outputs a detection signal corresponding to a change in a voltage of the first detection end caused by the detection input end and the first detection end being coupled by the coupling circuit responding to the first control signal.

2. The semiconductor memory device according to claim 1, wherein the output circuit outputs a detection signal notifying a presence of a leak current in the word line when the change in the voltage of the first detection end caused by the detection input end and the first detection end being electrically coupled by the coupling circuit exceeds a predetermined threshold.

3. The semiconductor memory device according to claim 2, wherein the coupling circuit includes a MOS transistor, and a capacitor that is serially connected to a source-drain passage of the MOS transistor.

4. The semiconductor memory device according to claim 3, further comprising a voltage clamping element that is biased by a voltage of the first detection end and a power source voltage on a high potential side, or the voltage of the first detection end and a power source voltage on a low potential side.

5. The semiconductor memory device according to claim 1, wherein the output circuit includes a CMOS inverter having an input end connected to the first detection end.

6. The semiconductor memory device according to claim 5, further comprising a clocked CMOS inverter to which an output signal of the output circuit is supplied, the clocked CMOS inverter supplies an output to the first detection end in synchrony with a predetermined timing signal.

7. The semiconductor memory device according to claim 1, further comprising:
a second detection end;
a second coupling circuit connected between the detection input end and the second detection end, the second coupling circuit electrically couples the detection input end and the second detection end according to a third control signal;
a third switching circuit having an output end connected to the second detection end, the third switching circuit supplies a power source voltage on a low potential side to the second detection end according to a fourth control signal; and
a fourth switching circuit having an output end connected to the first detection end.

8. The semiconductor memory device according to claim 1, further comprising a current source circuit connected to the detection input end.

9. The semiconductor memory device according to claim 8, wherein the current source circuit includes a switching circuit, and the switching circuit is turned off during when the detection input end is connected to the word line.

10. The semiconductor memory device according to claim 1, wherein the leak current detection circuit includes a second detection input end connected to a bit line.

11. The semiconductor memory device according to claim 10, wherein the semiconductor memory device is a NAND type flash memory.

12. The semiconductor memory device according to claim 1, further comprising:
a first leak current detection circuit including a plurality of coupling circuits that electrically couples a plurality of even-numbered word lines and the first detection end; and a second leak current detection circuit including a second detection end, and a plurality of coupling circuits that electrically couples a plurality of odd-numbered word lines and the second detection end.

13. A method for detecting a leak current of a semiconductor memory device, comprising:
charging a first word line of the semiconductor memory device to a first voltage, the first word line is connected to a detection input end;
charging a first detection end to a second voltage;
electrically coupling the detection input end and the first detection end at a timing when a predetermined time has elapsed; and
detecting a leak current of the semiconductor memory device from a potential change in the first detection end caused by coupling the detection input end and the first detection end.

14. The method for detecting a leak current of a semiconductor memory device according to claim 13, wherein
a switching circuit is turned on by a first control signal upon charging the first word line of the semiconductor memory device to the first voltage, the switching circuit connects the first word line and a supply end that supplies the first voltage,
a coupling circuit is turned on by a second control signal so as to electrically couple the detection input end and the first detection end at the timing when the predetermined time has elapsed, and
a voltage of the second control signal is lower than a voltage of the first control signal.

15. The method for detecting a leak current of a semiconductor memory device according to claim 14, wherein the first voltage upon charging the first word line of the semiconductor memory device and the second voltage upon electrically coupling the detection input end and the first detection end at the timing when the predetermined time has elapsed are different voltages.

16. The method for detecting a leak current of a semiconductor memory device according to claim 15, wherein a change in a potential of the first detection end is compared with a predetermined threshold upon detecting the leak current of the semiconductor memory device.

17. The method for detecting a leak current of a semiconductor memory device according to claim 16, wherein the first voltage upon charging the first word line of the semiconductor memory device is a power source voltage on the high potential side.

18. The method for detecting a leak current of a semiconductor memory device according to claim 14, further comprising:
applying a second voltage to a second word line adjacent to the first word line, the second voltage being different from a voltage with which the first word line is charged;
charging a second detection end to a power source voltage on the low potential side;
electrically coupling the detection input end to the second detection end after a predetermined time; and
supplying the power source voltage on the low potential side to the first detection end when a potential change of the second detection end caused by electrically coupling the detection input end and the second detection end is larger than a predetermined threshold.

19. A method for detecting a leak current of a semiconductor memory device, comprising:
applying a power source voltage on the high potential side to a detection input end connected to a first word line of the semiconductor memory device;
applying a data program voltage for a memory element of the semiconductor memory device to a second word line adjacent to the first word line of the semiconductor memory device over a predetermined time;
charging a detection end electrically coupled to the detection input end to the power source voltage on the high potential side over a predetermined time;
terminating the application of the voltage on the high potential side after a predetermined time has elapsed; and
detecting the leak current of the semiconductor memory device by comparing a potential change in the detection end caused after the termination of the application of the voltage on the high potential side to a predetermined threshold.

20. The method for detecting a leak current of a semiconductor memory device according to claim 19, wherein the semiconductor memory device is a NAND type flash memory.
